(19) United States
(12) Patent Application Publication
(10) Pub. No.: US 2013/0168020 A1
(43) Pub. Date: Jul. 4, 2013

(54) ETCHING DEVICE AND FOCUS RING

(71) Applicant: Kabushiki Kaisha Toshiba, Tokyo (JP)

(72) Inventors: Hisashi HASHIGUCHI, Mie-ken (JP); Hideo ETO, Mie-ken (JP); Makoto SAITO, Mie-ken (JP); Tetsuji NAKANO, Mie-ken (JP)

(73) Assignee: Kabushiki Kaisha Toshiba, Tokyo (JP)

(21) Appl. No.: 13/714,184

(22) Filed: Dec. 13, 2012

(30) Foreign Application Priority Data
Dec. 14, 2011 (JP) 2011-273214

(51) Int. Cl. H01J 37/32

(52) U.S. Cl. CPC H01J 37/32642
USPC 156/345.51

(57) ABSTRACT

An etching device includes a treatment target holding device holding a treatment target and a plasma generation device, etching the treatment target using generated plasma. The treatment target holding device includes a treatment target supporting member on which the treatment target is mounted, a ring-shaped focus ring that has a step part in a predetermined position, and a protective film containing yttria. The treatment target supporting member has a positioning pin that fixes the focus ring on a focus ring mounting region, the focus ring has a cavity part in a position corresponding to the positioning pin. The protective film is formed on a bottom surface and a side surface that configure the step part and on an upper surface of the focus ring corresponding to a formation position of the cavity part.

### CROSS-REFERENCE TO RELATED APPLICATION(S)

This application is based upon and claims the benefit of priority from Japanese Patent Application No. 2011-273214, filed on Dec. 14, 2011; the entire contents of (if multiple applications, all of) which are incorporated herein by reference.

### FIELD

Embodiments described herein relate to an etching device and a focus ring.

### BACKGROUND

In an etching device such as a reactive ion etching device that is used for manufacture of a semiconductor device, a focus ring is arranged so as to surround a circumference part of a wafer for the purpose of suppressing a deflection of an electric field in the circumference part of the wafer. During a plasma treatment, the focus ring is also etched because an electric field is also applied to the focus ring in addition to a supporting member that supports the wafer.

The focus ring is normally made of Si. The focus ring is more likely to be etched as well as etching of the wafer in a manufacture process of the semiconductor device, so that a life thereof is short. As a method for lengthening the life, there is a method in which an entire surface of the focus ring is covered by a protective film made of yttria or the like, which has a plasma tolerance. However, because the focus ring is more likely to be locally etched and the yttria film is locally removed when the entire surface of the focus ring is covered, the method is insufficient for lengthening the life. Also, there is a problem that covering the focus ring with a protective film having a film thickness having a sufficient plasma tolerance costs a lot because yttria is an expensive material that has yttrium, which is a rare-earth element, as a constituent element, and uses a lot of rear resources.

### BRIEF DESCRIPTION OF THE DRAWINGS

FIG. 1 is a cross-sectional view schematically illustrating one example of a configuration of an etching device.

FIG. 2 is a partial cross-sectional view schematically illustrating one example of a configuration of a periphery of a focus ring according to a first embodiment.

FIG. 3 is a partial cross-sectional view schematically illustrating one example of a normal configuration of the periphery of a focus ring.

FIGS. 4A-4C are graphs schematically illustrating a chronological change of the focus ring.

FIG. 5 is a partial cross-sectional view schematically illustrating one example of a configuration of the periphery of a focus ring according to a second embodiment.

FIGS. 6A and 6B are views illustrating one example of the structure of the focus ring.

FIGS. 7A-7C are graphs schematically illustrating the chronological change of the focus ring.

FIG. 8 is a cross-sectional view schematically illustrating one example of a configuration of an etching device.

FIG. 9 is a partial cross-sectional view schematically illustrating one example of a configuration of the periphery of an edge ring.

FIG. 10 is a partial cross-sectional view schematically illustrating one example of a configuration of the periphery of an edge ring according to a third embodiment.

FIG. 11 is a partial cross-sectional view schematically illustrating one example of a normal configuration of the periphery of a top edge ring.

FIGS. 12A and 12B are views schematically illustrating a chronological change of a top edge ring.

### DETAILED DESCRIPTION

According to one of embodiments disclosed in the application, an etching device includes a treatment target holding device that holds a treatment target in a chamber, and a plasma generation device that turns gas introduced into the chamber into plasma. The etching device etches the treatment target using generated plasma, the treatment target holding device includes a treatment target supporting member that serves as an electrode and on which the treatment target is mounted, a ring-shaped focus ring that is provided in an outer circumference of the treatment target supporting member and that has a step part in an inner circumference having a height lower than those of other portions and having the same height as those of an upper surface of the treatment target supporting member, and a protective film containing yttria that is provided in a predetermined region of the focus ring. The treatment target supporting member has a positioning pin that fixes the focus ring on a focus ring mounting region on which the focus ring is mounted, the focus ring has a cavity part in a position corresponding to the positioning pin, and the protective film is formed on a bottom surface and a side surface that configure the step part of the focus ring and on an upper surface of the focus ring corresponding to a formation position of the cavity part.

In another view, certain embodiments provide a focus ring that is provided in an outer circumference of a treatment target supporting member arranged in a chamber of an etching device, that includes a step part in an inner circumference that is lower than other portions and has the substantially same height as those of an upper surface of the treatment target supporting member, and that has a ring shape. The focus ring includes a cavity part arranged in a position corresponding to a positioning pin that fixes the focus ring provided on the treatment target supporting member, and a protective film containing yttria, which is provided on a bottom surface and a side surface that configure the step part and on an upper surface of the focus ring corresponding to a formation position of the cavity part.

Hereinafter, etching devices and focus rings according to various embodiments will be described in detail with reference to the accompanying drawings. In addition, it is noted that these embodiments do not intend to limit the scope of the inventions.

### First Embodiment

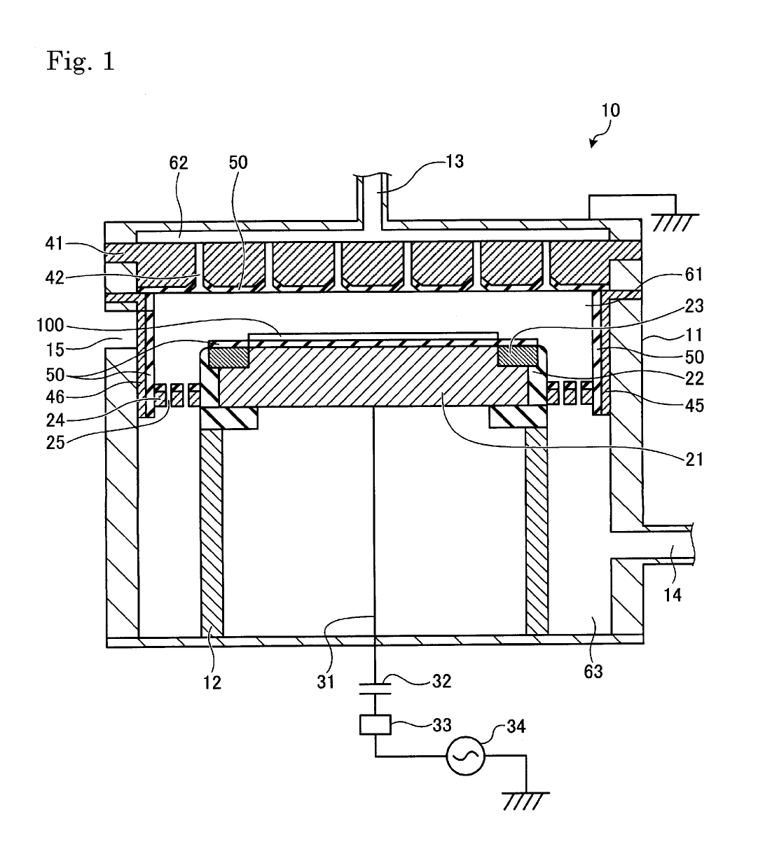

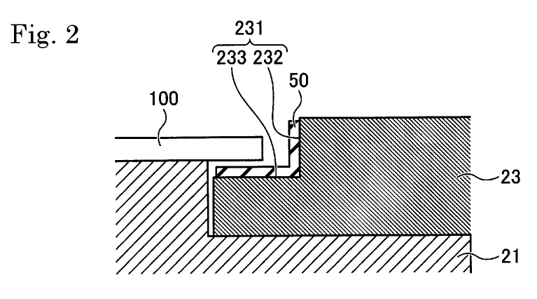

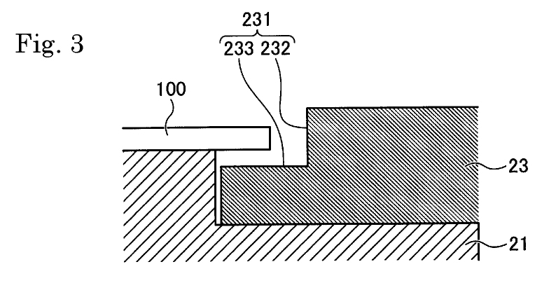

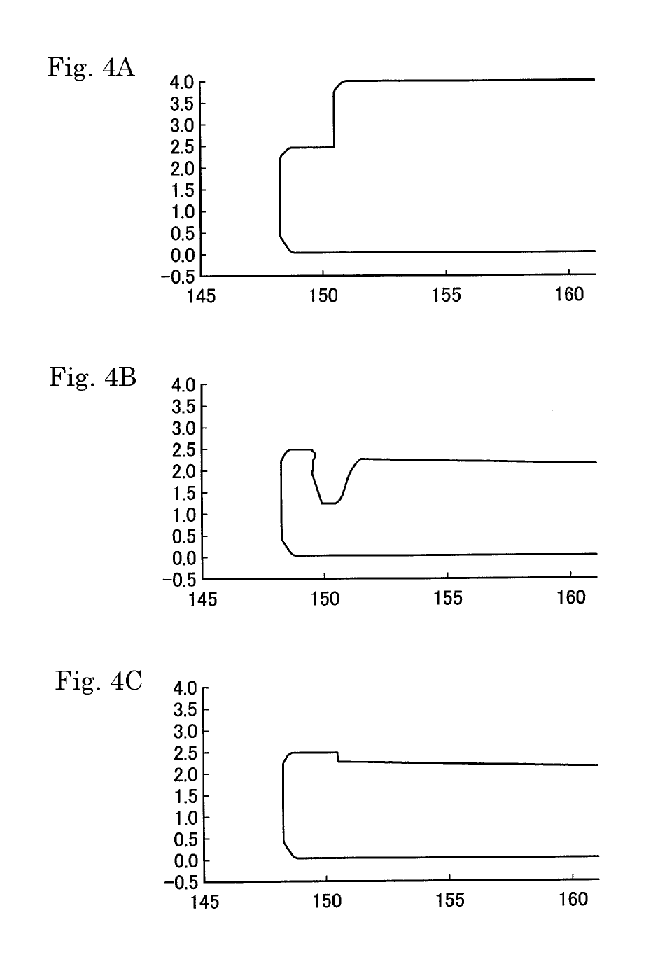

FIG. 1 is a cross-sectional view schematically illustrating one example of a configuration of an etching device. FIG. 2 is a partial cross-sectional view schematically illustrating one example of a configuration of a periphery of a focus ring according to a first embodiment. FIG. 3 is a partial cross-sectional view schematically illustrating one example of a normal configuration of the periphery of a focus ring. FIG. 4 is a view schematically illustrating a chronological change of the focus ring. Herein, as an etching device 10, a parallel plate type reactive ion etching (ME) device is used as an example.

As illustrated in FIG. 1, the etching device 10 includes a tightly-configured chamber 11 made of aluminum, for example. In the chamber 11, a supporting table 21 is provided that horizontally supports a wafer 100, which is a treatment target, and that serves as a lower electrode. On a surface of the supporting table 21, a holding mechanism (not illustrated) such as an electrostatic chuck mechanism is provided. The electrostatic chuck mechanism electrostatically holds the wafer 100. In an outer circumference part near the surface of the supporting table 21, a focus ring 23 made of Si is provided. An insulator ring 22 is arranged so as to cover side surfaces of a structure body of the supporting table 21 and the focus ring 23 and the circumference part of a bottom surface of the supporting table 21. The focus ring 23 is a member for adjusting an electric field such that the electric field does not deflect with respect to a vertical direction (direction perpendicular to a wafer surface) in the circumference part of the wafer 100.

Also, the supporting table 21 is supported on a supporting part 12 through the insulator ring 22 therebetween such that the supporting table 21 is positioned near the center of the chamber 11. The supporting part 12 projects upward in the vertical direction from a bottom wall in a cylinder shape. A baffle plate 24 is provided between the insulator ring 22 and a side wall of the chamber 11. The baffle plate 24 has a plurality of gas outlet holes 25 penetrating in a thickness direction of the plate. Also, a power supply line 31 that supplies high frequency power is connected with the supporting table 21, and a blocking condenser 32, a matching box 33, and a high frequency power source 34 are connected with the power supply line 31. During the plasma treatment, high frequency power at a predetermined frequency is supplied to the supporting table 21 from the high frequency power source 34. Herein, the supporting table 21, the power supply line 31, the blocking condenser 32, the matching box 33, and the high frequency power source 34 configure a plasma generation device.

A shower head 41 that serves as an upper electrode is provided above the supporting table 21 so as to face the supporting table 21 that serves as the lower electrode. The shower head 41 is fixed to a side wall of the chamber 11 near an upper portion that is distanced at a predetermined distance from the supporting table 21 so as to face the supporting table 21 in parallel. With such configuration, the shower head 41 and the supporting table 21 configure a pair of parallel plate electrodes. Also, a plurality of gas discharge ports 42 penetrating in a thickness direction of the plate are provided in the shower head 41.

A gas supply port 13 that is used during the plasma treatment and through which treatment gas is supplied is provided near the upper portion of the chamber 11, and a gas supply device (not illustrated) is connected with the gas supply port 13 via a pipe.

In a lower portion of the chamber 11 below the supporting table 21 and the baffle plate 24, a gas exhaust port 14 is provided. A vacuum pump (not illustrated), which is an exhaust device, is connected with the gas exhaust port 14 via a pipe.

Also, on a side wall of the chamber 11 in a region separated between the baffle plate 24 and the shower head 41, a deposition shield 45 is provided. The deposition shield 45 prevents a deposit generated during the plasma treatment from adhering to the side wall of the chamber 11. Also, in a side wall portion of the chamber 11 in a predetermined position, an opening part 15 is provided through which the wafer 100 is taken in and out. In a part of the deposition shield 45 corresponding to the opening part 15, a shutter 46 is provided. The shutter 46 has a function to separate the outside of the chamber 11 from the inside of the chamber 11, and is opened and closed so as to connect the opening part 15 with the inside of the chamber 11.

A region in the chamber 11 separated by the supporting table 21, the baffle plate 24, and the shower head 41 configure a plasma treatment room 61. An upper region in the chamber 11 separated by the shower head 41 configures a gas supply room 62. A lower region in the chamber 11 separated by the supporting table 21 and the baffle plate 24 configures a gas exhaust room 63.

A brief description of a treatment in the etching device 10 as configured above is given. Initially, the wafer 100, which is a treatment target, is mounted on the supporting table 21 and is clamped by the electrostatic chuck mechanism for example. Next, an air vacuum is performed in the chamber 11 by the vacuum pump (not illustrated) connected to the gas exhaust port 14. At this point, the gas exhaust room 63 and the plasma treatment room 61 are connected by the gas outlet holes 25 provided in the baffle plate 24, and thereby vacuum drawing for the entire inside of the chamber 11 is performed by the vacuum pump linked to the gas exhaust port 14.

Then, when a pressure of the inside of the chamber 11 reaches a predetermined pressure, because the plasma treatment room 61 and the gas supply room 62 are connected by the gas discharge ports 42 of the shower head 41, treatment gas is supplied from the gas supply device (not illustrated) to the gas supply room 62 and is supplied to the plasma treatment room 61 through the gas discharge ports 42 of the shower head 41. When the pressure of the inside of the plasma treatment room 61 reaches a predetermined pressure, high frequency voltage is applied to the supporting table 21 (lower electrode) under a state where the shower head 41 (upper electrode) is grounded so that plasma is generated in the plasma treatment room 61. At this point, by a self bias due to the high frequency voltage, a potential gradient between the plasma and the wafer 100 occurs on a lower electrode side, and ions in plasma gas is accelerated toward the supporting table 21. As a result, an anisotropy etching treatment is performed.

During the anisotropy etching treatment, not only the wafer 100 but also the focus ring 23 and the insulator ring 22 are etched by ions and/or radicals. As described above, surfaces of components on sides contacting a plasma generation region, that is surfaces of the components of the plasma treatment room 61, are more likely to be deteriorated because they are exposed to plasma, and therefore a protective film 50 having an etching tolerance during the plasma treatment is provided.

Next, a description is given of the focus ring 23 according to the present embodiment on which the protective film 50 is formed. As illustrated in FIG. 2, the focus ring 23 is provided in the outer circumference of the upper portion of the supporting table 21 that supports the wafer 100. A step part 231 on which the wafer 100 is mounted is provided on a supporting table 21 side of the focus ring 23. A bottom surface 233 configuring the step part 231 of the focus ring 23 is provided at a height almost the same as that of an upper surface of the supporting table 21. An upper surface of a region of the focus ring 23 where the step part 231 is not included is provided at a height almost the same as or slightly higher than that of an upper surface of the wafer 100 when the wafer 100 is mounted on the supporting table 21. Also, because an area of the upper surface of the supporting table 21 is smaller than an area of the wafer 100, the wafer 100 is mounted on a wafer mounting region configured with the upper surface of the supporting table 21 and the bottom surface 233 of the step part 231 of the focus ring 23. Normally, because the wafer 100 has a circular shape, the shape of the focus ring 23 on the top plan view is a ring shape.

As illustrated in FIG. 3, a size of the wafer mounting region is normally formed to be larger (wider) than a size (diameter) of the wafer 100. Therefore, under a state where the wafer 100 is mounted in the wafer mounting region, there is a gap between an end part of the wafer 100 and a side surface 232 configuring the step part 231 of the focus ring 23.

A horizon axis of each of the graphs of FIGS. 4A-4C indicates the position of the focus ring 23 in the horizontal direction, and a vertical axis indicates the thickness of the focus ring 23. Also, FIG. 4A illustrates a portion of a cross-section profile of the manufactured focus ring 23 at an initial state. FIG. 4B illustrates a portion of a cross-section profile of the focus ring 23 after the focus ring 23 is etched for a predetermined period. FIG. 4C illustrates a portion of a cross-section profile of the focus ring 23 on which the protective film 50 according to the present embodiment is formed after the focus ring 23 is etched for the predetermined period.

FIGS. 4A-4C illustrate cases where the focus ring 23 is made of Si. As illustrated in FIG. 4A, at the initial state of the manufactured focus ring 23, the thickness of the focus ring 23 except for the step part 231 is substantially constant. Then, as the focus ring 23 is used over a long period of time, an exposed portion of the focus ring 23 is etched. Specifically, while the upper surface except for the step part 231 is etched almost evenly, a portion corresponding to the gap generated between the wafer 100 and the side surface 232 configuring the step part 231 of the focus ring 23 as illustrated in FIG. 3 is etched. As a result, as illustrated in FIG. 4B, in the portion corresponding to the gap, the thickness of the focus ring 23 becomes thinner as compared to other portion, and the life is determined depending on the thickness of this portion.

Then, according to the first embodiment, the protective film 50 having the plasma tolerance is formed on the side surface 232 and the bottom surface 233 configuring the step part 231 of the focus ring 23. The thickness of the formed protective film 50 is preferably approximately 0.1-200 μm. When the thickness is thinner than 0.1 μm, the position where the protective film 50 is formed is etched more quickly than the other region, so that the life of the focus ring 23 cannot be lengthened. When the thickness is thicker than 200 μm, even when the region where the protective film 50 is not formed has a thickness of the end of the life, the protective film 50 remains, so that the remained protective film 50 is to be waste. Therefore, the thickness of the protective film 50 is preferably set to be within the above-described range. Practically, the thickness of the protective film 50 is determined such that the thickness of the portion corresponding to the gap between the wafer 100 and the side surface 232 configuring the step part 231 of the focus ring 23 is almost the same as a replacement thickness when the thickness of the region of the focus ring 23 except for the step part 231 is the replacement thickness. The replacement thickness means a thickness with which the focus ring 23 cannot function as the focus ring 23. As one example, the thickness of the protective film 50 is determined such that a period taken for removing an amount of Si corresponding to a fall amount of the step part 231 of the focus ring 23 by etching and a period taken for removing the portion of the protective film 50 corresponding to the gap by etching are almost the same.

When the protective film 50 is formed on the step part 231 of the focus ring 23 as described above, as illustrated in FIG. 4C, the thickness of the focus ring 23 after the etching treatment for a predetermined period becomes substantially even due to the existence of the protective film 50 having the plasma tolerance.

As the protective film 50, a film containing yttrium oxide particles for example (hereinafter, referred to as an yttria film) can be used. Any film can be used as long as the film is an yttria film. However, specifically, an yttria film (hereinafter, referred to as an yttria film in a semi-molten state) is preferred in which at least surfaces of the particles are in a molten state, adjacent particles are coupled, solidified yttrium oxide particles are included, and particle borders cannot be partially observed. The yttria film in the semi-molten state includes yttrium oxide particles and has a film thickness of 10 μm or more, a film density of 90% or more. An area ratio of yttrium oxide particles having observable particle borders existed in a unit area of 20 μm×20 μm is 0-80%. An area ratio of yttrium oxide particles having not-observable particle borders existed in a unit area of 20 μm×20 μm is 20-100%.

The film thickness of the yttria film in the semi-molten state is preferably 10 μm or more. With the film thickness of less than 10 μm, the effect of the provided yttria film cannot be sufficiently obtained, and the yttria film may rather be a cause of film peeling. The upper limit of the thickness of the yttria film is not specifically set. However, with an excessively thick thickness, an extra effect cannot be obtained, and cracking is more likely to occur due to the stock of internal force, causing cost-up. Therefore, the thickness of the yttria film is 10-200 μm, and is preferably 50-150 μm.

Also, the film density is 90% or more, preferably 95% and more, further preferably 99% or more and 100% or less. When a lot of voids exist in the yttria film, erosion such as plasma attack progresses from the voids, so that the life of the oxide film is reduced. Therefore, it is preferred that especially the surface of the yttria film includes few voids.

Note, the film density and void ratio are opposite terminologies. The film density of 90% or more means the same as the void ratio of 10% or less. A measuring method of the film density is cutting the oxide film in the film thickness direction, taking an 500 times enlarged picture of the cross-sectional structure by an optical microscope, and calculating the area ratio of the voids captured on the picture. Then, the film density is calculated by “film density (%)=100−area ratio of voids.” For the calculation of the film density, an area of a unit area of 200 μm×200 μm is analyzed. Note, when the film thickness is thin, plural parts are measured until the total of the unit area reaches 200 μm×200 μm.

Furthermore, when the area ratio of “yttrium oxide particles having observable particles borders” exceeds 80%, because destruction heat due to collision is insufficient, the deposition turns to a drastically cooling state. As a result, the density of the film is increased and the coupling force of the film is decreased, and in some cases a crack is caused. Therefore, it is preferred that the area ratio of “yttrium oxide particles having observable particle borders” is 0-80%.

Also, a surface roughness Ra of the yttria film is preferably 3 μm or less. When the unevenness of the surface of the yttria film is large, plasma attack and the like is more likely to concentrate, and this may decrease the life of the film. A measurement of the surface roughness Ra follows JIS-B-0601-1994. Preferably, the surface roughness Ra is 2 μm or less.

Furthermore, it is preferred that an average particle diameter of the yttrium oxide particle with observable particle border is 2 μm or less and that an average particle diameter of all yttrium oxide particles including the yttrium oxide particles with observable particle borders is 5 μm or less.

Such protective film 50 can be formed on the step part 231 of the focus ring 23 using a thermal spraying method, a chemical vapor deposition (CVD) method, an aerosol deposition (AD) method, a cold spray method, a gas deposition method, a electro-statistic particle impact deposition method, and a shock compaction method, etc.

Especially, the above-described yttria film in the semi-molten state can be formed by a shock sintering method by accelerating the injection speed of yttrium oxide particles in a state where the yttrium oxide particles are not molten or only the surface is molten and by controlling to keep a high speed more than a threshold speed at which particles begin to deposit. In the shock sintering method, slurry containing the yttria particles is supplied to a combustion frame and the particles are injected from an injection nozzle, and the particles collide with a base material at a high speed (for example, more than speed of sound), sintering combination occurs by the crush heat of the particles due to the collision, and the film is formed. By this, there is a tendency that the film is more likely to be formed with the yttrium oxide particles in the yttria film in a crashed shape not in the particle shape of material powder. Also, the yttrium oxide particle with the molten surface layer couples with an adjacent yttrium oxide particle due to crash heat generated by collision with the base material, and the yttria film including the yttrium oxide particles with not-observable particle borders are formed. At this time, by the crash heat generated when the yttrium oxide particle collides with the base material, not only the surface layer of the yttrium oxide particle but also the entire particle may be molten, and the same yttria film is also formed in this case. Also, in the yttrium oxide particle that doesn't melt a surface layer, at least a surface thereof may melt due to the crash heat generated by collision with the base material, and an yttria film including the yttrium oxide particles with not-observable border with the adjacent yttrium oxide particle is formed. As described above, when high-speed injection is used, material powder is not melted and injected as a thermal spraying. Therefore, it is possible to deposit yttrium particles as material powder while a powder shape of the yttrium oxide particle is substantially maintained. As a result, stress inside the film is not generated, and an yttria film having minuteness (high film density) and strong coupling force can be formed.

By adjustment of a slurry supply position for supplying slurry to combustion flame and a distance between a base material and the injection nozzle for injecting particles, an area ration of particles, which are in the yttria film formed in the base material, with observable particle borders and particles, which are in the yttria film formed in the base material, with not-observable particle borders can be adjusted.

As described above, according to the first embodiment, the protective film 50 including yttria is formed on the surface configuring the step part 231 on which the wafer 100 of the focus ring 23 is mounted. By doing this, it is possible to prevent the thickness of the portion corresponding to the gap from being thinner before the thickness of the portion except for the step part 231 of the focus ring 23 becomes the predetermined thickness. The thinner thickness is cause when a portion corresponding to the gap between the end part of the wafer 100 and the side surface 232 of the step part 231 of the focus ring 23, which is generated when the wafer 100 is mounted on the wafer mounting region, is etched more than the other region. In other words, replacement time of the focus ring 23 is not determined by the thickness of the portion of the focus ring 23 corresponding to the gap. The focus ring 23 is replaced when the thickness of the other portion (portion except for the step part 231) is the predetermined thickness. Therefore, there is the effect that the life of the focus ring 23 can be lengthened. Also, the protective film 50 including yttria is formed only on the step part 231 of the focus ring 23. Therefore, as compared to the case where the entire focus ring 23 is covered by the protective film 50, there is an effect that an usage amount of yttrium, which is a rare-earth element, can be reduced and resource conservation and low cost can be realized.

### Second Embodiment

In the first embodiment, as an example, the etching device having the structure in which the focus ring is fit and fixed to the supporting table was given. In a second embodiment, as an example, a case where the focus ring is fixed by a positioning pin that is provided on the supporting table is given.

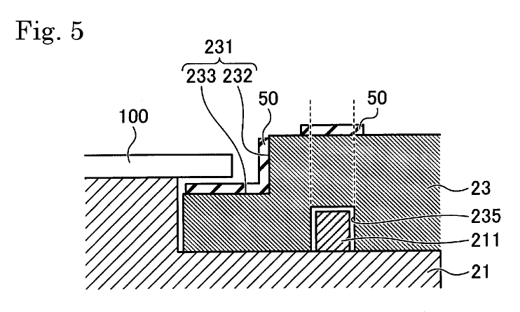

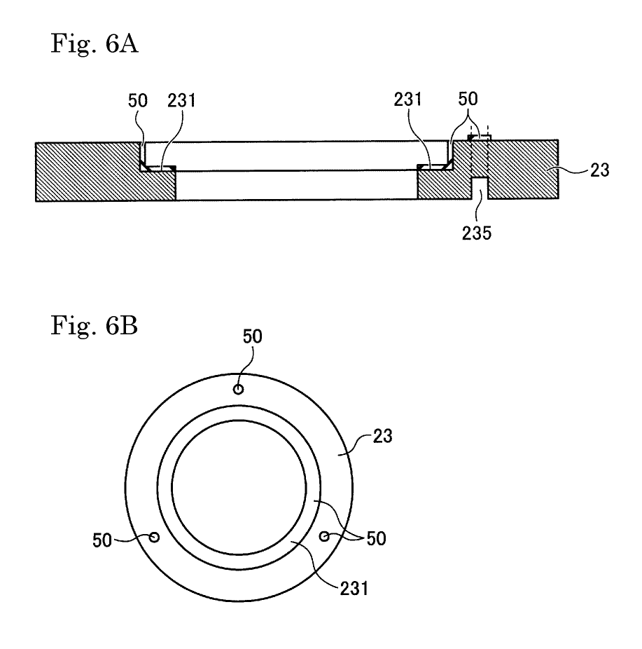

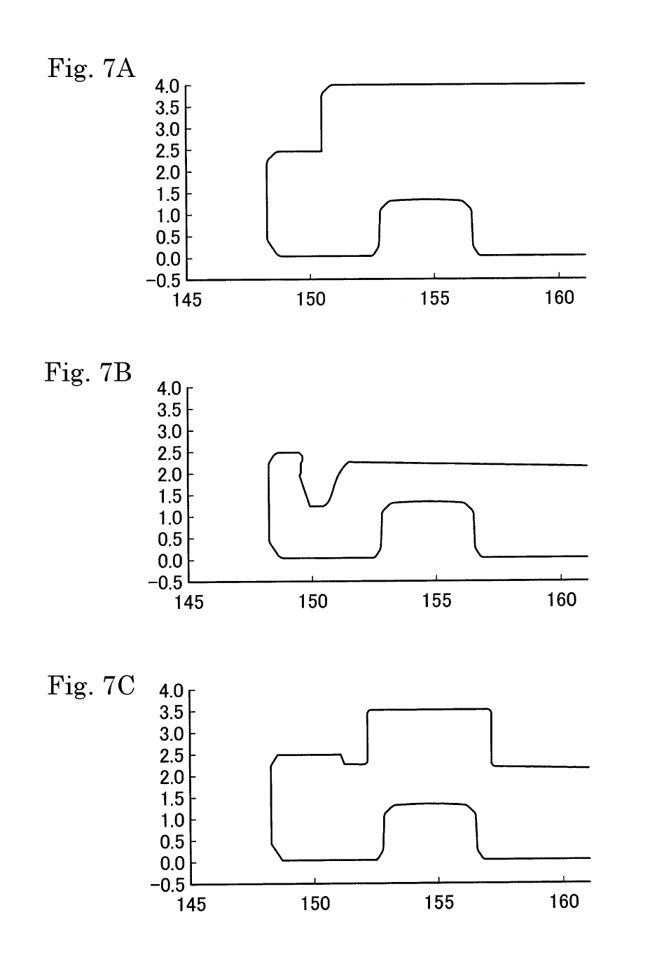

FIG. 5 is a partial cross-sectional view schematically illustrating one example of a configuration of the periphery of a focus ring according to the second embodiment. FIGS. 6A and 6B are views illustrating one example of the structure of the focus ring. FIG. 6A is a cross sectional view and FIG. 6B is a top plan view. FIG. 7 is a view schematically illustrating the chronological change of the focus ring.

As illustrated in FIG. 5, according to the second embodiment, the positioning pin 211 is provided projected in a predetermined position on the mounting region of the focus ring 23 of the supporting table 21. Three positioning pins 211 are arranged by 120° on the supporting table 21 on the same circumference from the center of the supporting table 21. The diameter of the positioning pin 211 should just be a size with which the focus ring 23 can be fixed without greatly moving on the supporting table 21, and can be set at 5 mm, for example.

Also, on the lower surface of the focus ring 23, a cavity part 235 is provided so as to fit the positioning pin 211. As illustrated in FIG. 6B, the three cavity parts 235 provided in the focus ring 23 are also provided in positions by 120° on the same circumference from the center of the focus ring 23. The cavity part 235 has a diameter almost the same as the diameter of the positioning pin 211 such that the positioning pin 211 fits the cavity part 235 without friction, and more preferably the diameter of the cavity part 235 is designed to be slightly larger than the diameter of the positioning pin 211. For fixing the focus ring 23 on the supporting table 21, after positioning the focus ring 23 such that the positioning pins 211 on the supporting table 21 fit the cavity parts 235, the focus ring 23 is mounted on the supporting table 21.

Chronological change by etching of an outline of the focus ring 23 having the cavity parts 235 fitting such positioning pins 211 is explained. A horizon axis of each of the graphs of FIGS. 7A-7C indicates the position of the focus ring 23 in the horizontal direction, and a vertical axis indicates the thickness of the focus ring 23. Also, FIG. 7A illustrates a portion of a cross-section profile of the manufactured focus ring 23 at an initial state. FIG. 7B illustrates a portion of a cross-section profile of the focus ring 23 after the focus ring 23 is etched for a predetermined period. FIG. 7C illustrates a portion of a cross-section profile of the focus ring 23 on which the protective film 50 according to the present embodiment is formed after the focus ring 23 is etched for the predetermined period.

FIGS. 7A-7C illustrate cases where the focus ring 23 is made of Si. As illustrated in FIG. 7A, at the initial state of the manufactured focus ring 23, the thickness of the focus ring 23 except for the step part 231 is substantially constant. Then, as the focus ring 23 is used over a long period of time, an exposed portion of the focus ring 23 is etched. Specifically, while the upper surface except for the step part 231 is etched almost evenly, a portion corresponding to the gap generated between the wafer 100 and the side surface 232 configuring the step part 231 of the focus ring 23 as illustrated in FIG. 3 is etched. As a result, as illustrated in FIG. 7B, in the portion corresponding to the gap and in the portion corresponding the formation position of the positioning pin 211 (cavity part 235), the thickness of the focus ring 23 becomes thinner as compared to the other portion. Specifically, in the portion corresponding to the formation position of the positioning pin 211, the thickness is reduced by the thickness corresponding to the cavity part 235, and the life is determined depending on the thickness of this portion.

Then, according to the second embodiment, as illustrated in FIGS. 5 and 6A, the protective film 50 having the plasma tolerance is also formed on upper surfaces of the focus ring 23 corresponding to the formation positions of the positioning pins 211 in addition to the side surface 232 and the bottom surface 233 configuring the step part 231 of the focus ring 23. The thickness of the formed protective film 50 is preferably approximately 0.1-200 μm. Practically, the thickness of the protective film 50 is determined such that the thickness of the portion corresponding to the gap between the wafer 100 and the side surface 232 configuring the step part 231 of the focus ring 23 and the thickness of the focus ring 23 at the formation position of the positioning pin 211 are almost the same as the replacement thickness when the thickness of the region of the focus ring 23 except for the step part 231, where the protective film 50 is not provided, is the replacement thickness. The replacement thickness means a thickness with which the focus ring 23 cannot function as the focus ring 23. As one example, the thickness of the protective film 50 is determined such that a period taken for removing Si by etching until that the region where the protective film 50 is not provided within the region except for the step part 231 becomes the replacement thickness, a period taken for removing the protective film 50 and Si by etching until that the thickness of the portion corresponding to the gap becomes the replacement thickness, and a period taken for removing the protective film 50 and Si by etching until that the thickness of the formation position of the positioning pin 211 becomes the replacement thickness are almost the same.

In the case where the protective film 50 is formed on the step part 231 of the focus ring 23 as described above, as illustrated in FIG. 7C, due to the existence of the protective film 50 having the plasma tolerance, the thickness of the focus ring 23 after the etching treatment for a predetermined period become substantially even.

The protective film 50 used in the second embodiment is the same as the protective film 50 described in the first embodiment, so a description thereof is omitted. Also, the same reference numbers are given to elements the same as those according to the first embodiment, and descriptions thereof are omitted.

Also with the second embodiment, the same effect as those of the first embodiment can be obtained.

### Third Embodiment

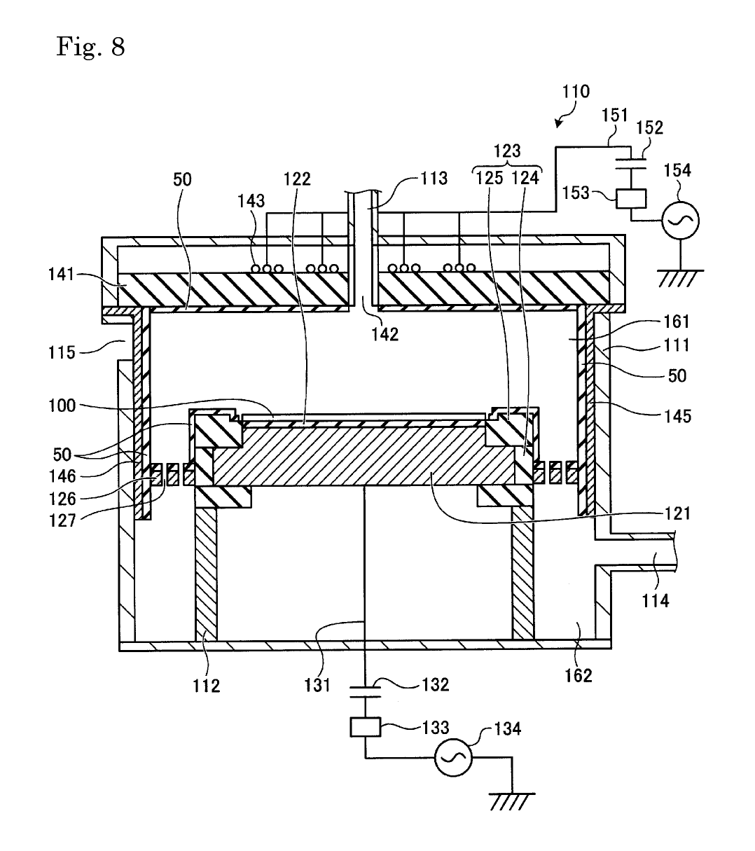

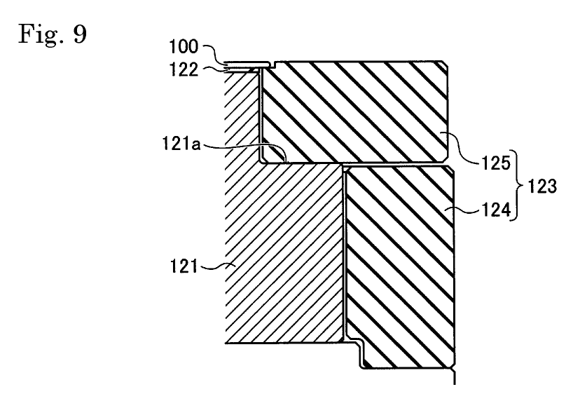

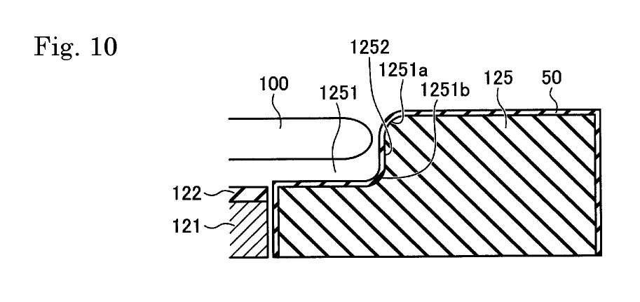

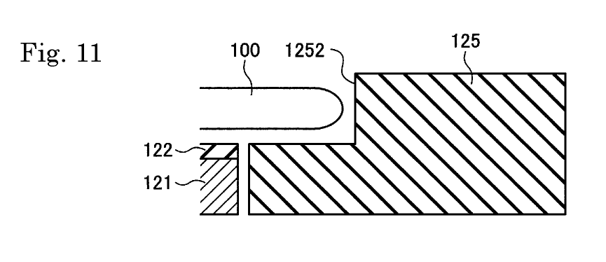

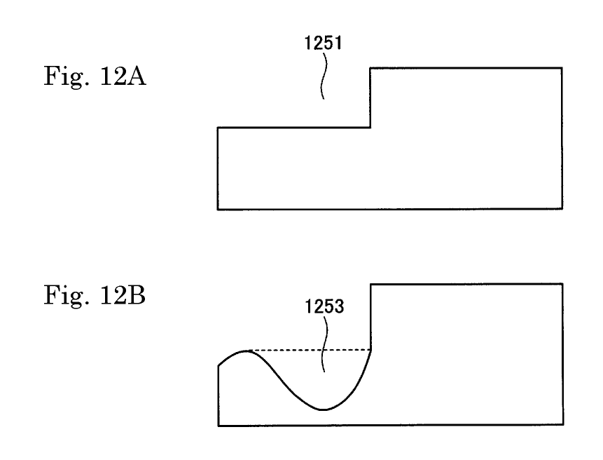

FIG. 8 is a cross-sectional view schematically illustrating one example of a configuration of an etching device. FIG. 9 is a partial cross-sectional view schematically illustrating one example of a configuration of the periphery of an edge ring. FIG. 10 is a partial cross-sectional view schematically illustrating one example of a configuration of the periphery of an edge ring according to a third embodiment. FIG. 11 is a partial cross-sectional view schematically illustrating one example of a normal configuration of the periphery of a top edge ring. FIG. 12 is a view schematically illustrating a chronological change of a top edge ring. Herein, as an etching device 110, an inductive coupling plasma-ME device is used as an example.

As illustrated in FIG. 8, the etching device 110 includes a tightly-configured chamber 111 made of aluminum, for example. In the chamber 111, a supporting table 121 is provided that horizontally supports the wafer 100, which is a treatment target. On a surface of the supporting table 121, a holding mechanism (not illustrated) such as an electrostatic chuck mechanism is provided. The electrostatic chuck mechanism electrostatically holds the wafer 100. A base material of the supporting table 121 is aluminum, and a holding surface 122 for the wafer 100 is configured of alumina.

An edge ring 123 made of an insulating material is provided so as to cover a side surface and an upper part of a circumference part of the supporting table 121. As illustrated in FIG. 9, the edge ring 123 is configured with a bottom edge ring 124 and a top edge ring 125. The bottom edge ring 124 is arranged around the supporting table 121. The top edge ring 125 in a ring shape is mounted on the bottom edge ring 124 and on the circumference part of the supporting table 121. In the circumference part of the supporting table 121, the step part is provided, and the height of a bottom surface 121a of the step part and the height of the upper surface of the bottom edge ring 124 are almost the same. Then, the bottom surface 121a of the step part of the supporting table 121 and the upper surface of the bottom edge ring 124 configure a top edge ring mounting region on which the top edge ring 125 is mounted. The bottom edge ring 124 is made of quarts and has the functions of protecting a side wall of the supporting table 121 and of securing pressure-resistance. Also, the top edge ring 125 is configured of quarts, alumina covered by an yttria film, or the like, and has the functions of protecting the supporting table 121 in the periphery part of the wafer 100 and of maintaining a sheath electric field of the edge part of the wafer 100.

Also, the supporting table 121 is supported on a supporting part 112 through an insulating material therebetween such that the supporting table 121 is positioned near the center of the chamber 111. The supporting part 112 projects upward in the vertical direction from a bottom wall near the center of the chamber 111 in a cylinder shape. A baffle plate 126 is provided between the edge ring 123 and a side wall of the chamber 111. The baffle plate 126 has a plurality of gas outlet holes 127 penetrating in a thickness direction of the plate. Also, a power supply line 131 that supplies high frequency power is connected with the supporting table 121, and a blocking condenser 132, a matching box 133, and a high frequency power source 134 are connected with the power supply line 131. During the plasma treatment, high frequency power at a predetermined frequency is supplied to the supporting table 121 from the high frequency power source 134.

A top plate 141 made of quarts or alumina is provided above the supporting table 121 so as to face the supporting table 121 that serves as the lower electrode. The top plate 141 is fixed to a side wall of the chamber 111 near an upper portion that is distanced at a predetermined distance from the supporting table 121. Also, a gas discharge port 142 penetrating in a thickness direction of the plate are provided near the center of the top plate 141.

A gas supply pipe 113 that is used during the plasma treatment and through which treatment gas is supplied is provided near the upper portion of the chamber 111. A gas supply device is connected with a not-illustrated end part of the gas supply pipe 113, and the other end part is connected with a gas discharge port 142 of the top plate 141 in the chamber 111.

On the upper surface of the top plate 141, an antenna part 143 is provided. A power supply line 151 that supplies high frequency power is connected with the antenna part 143. A blocking condenser 152, a matching box 153, and a high frequency power source 154 on ICP side are connected with the power supply line 151. Herein, the quarts plate 141, the antenna part 143, the power supply line 151, the blocking condenser 152, the matching box 153, and the high frequency power source 154 configure a plasma generation device. In other words, for generating plasma, high frequency power at the predetermined frequency is supplied from the high frequency power source 154 to the top plate 141, and treatment gas turns to plasma.

In a lower portion of the chamber 111 below the supporting table 121 and the baffle plate 126, a gas exhaust port 114 is provided. A vacuum pump (not illustrated), which is an exhaust device, is connected with the gas exhaust port 14 via a pipe.

Also, on a side wall of the chamber 111 in a region separated between the baffle plate 126 and the top plate 141, a deposition shield 145 is provided. The deposition shield 145 prevents a deposit generated during the plasma treatment from adhering to the side wall of the chamber 111. Also, in a side wall portion of the chamber 111 in a predetermined position, an opening part 115 is provided through which the wafer 100 is taken in and out. In a part of the deposition shield 145 corresponding to the opening part 115, a shutter 146 is provided. The shutter 46 has a function to separate the outside of the chamber 111 from the inside of the chamber 111, and is opened and closed so as to connect the opening part 115 with the inside of the chamber 111.

A region in the chamber 111 separated by the supporting table 121, the baffle plate 124, and the top plate 141 configures a plasma treatment room 161. A lower region in the chamber 111 separated by the supporting table 121 and the baffle plate 126 configure a gas exhaust room 162.

A brief description of a treatment in the etching device 110 as configured above is given. Initially, the wafer 100, which is a treatment target, is mounted on the supporting table 121 and is clamped by the electrostatic chuck mechanism for example. Next, an air vacuum is performed in the chamber 111 by the vacuum pump (not illustrated) connected to the gas exhaust port 114. At this point, the gas exhaust room 162 and the plasma treatment room 161 are connected by the gas outlet holes 127 provided in the baffle plate 126, and thereby vacuum drawing for the entire inside of the chamber 111 is performed by the vacuum pump linked to the gas exhaust port 114.

Then, when a pressure of the inside of the chamber 111 reaches a predetermined pressure, treatment gas is supplied from the gas supply device (not illustrated) into the plasma treatment room 161 through the gas supply pipe 161. When the pressure of the inside of the plasma treatment room 161 reaches a predetermined pressure, high frequency voltage is applied to the antenna part 143 from the high frequency power source 154 on the ICP side, so that plasma is generated in the plasma treatment room 161. Also, when plasma is generated, high frequency voltage is applied from the high frequency power source 134 on a bias side to the supporting table 121. By the bias voltage due to the high frequency voltage, a potential gradient between the plasma and the wafer 100 occurs on the supporting table 121 side, and ions in plasma gas is accelerated toward the supporting table 121. As a result, an anisotropy etching treatment is performed.

During the anisotropy etching treatment, not only the wafer 100 but also the focus ring 123 is etched by ions and/or radicals. As described above, surfaces of components on sides contacting a plasma generation region, that is surfaces of the components of the plasma treatment room 161, are more likely to be deteriorated because they are exposed to plasma, and therefore the protective film 50 having an etching tolerance during the plasma treatment is provided.

Next, a description is given of the top edge ring 125 according to the present embodiment on which the protective film 50 is formed. As illustrated in FIG. 10, the top edge ring 125 is provided in the outer circumference of the upper portion of the supporting table 121 that supports the wafer 100. A step part 1251 on which the wafer 100 is mounted is provided on a supporting table 121 side of the top edge ring 125. An upper surface of a region except for the step part 1251 of the top edge ring 125 is provided at a height almost the same as or slightly higher than that of an upper surface of the wafer 100 when the wafer 100 is mounted on the supporting table 121. Also, because an area of the upper surface of the supporting table 121 is smaller than an area of the wafer 100, the wafer 100 is mounted on a wafer mounting region configured with the upper surface of the supporting table 121 and the step part 1251 of the top edge ring 125. Normally, because the wafer 100 has a circular shape, the shape of the top edge ring 125 on the top plan view is a ring shape.

As illustrated in FIG. 11, a size of the wafer mounting region is normally formed to be larger (wider) than a size (diameter) of the wafer 100. Therefore, under a state where the wafer 100 is mounted in the wafer mounting region, there is a gap between an end part of the wafer 100 and a side surface 1252 configuring the step part 1251 of the top edge ring 125.

FIG. 12A is a partial cross section (profile) of the manufactured top edge ring 125 at an initial state. The thickness of the top edge ring 125 is substantially constant at the step part 1251. Then, as the top edge ring 125 is used over a long period of time, an exposed portion of the top edge ring 125 is etched. FIG. 12 is a partial cross section (profile) of the top edge ring 125 after the top edge ring 125 is used over a long period of time. As illustrated in FIG. 12B, while the upper surface except for the step part 1251 is etched almost evenly, a portion corresponding to the gap generated between the wafer 100 and the side surface 1252 configuring the step part 1251 of the top edge ring 125 as illustrated in FIG. 11 is etched, and a concave portion 1253 is formed 1253. As a result, in the concave part 1253, the thickness of the top edge ring 125 becomes thinner as compared to the other portion, and the life is determined depending on the thickness of this portion.

According to the third embodiment, two edge parts 1251a and 1251b configuring the step part 1251 of the top edge ring 125 are rounded, and the protective film 5 having the plasma tolerance is formed on the upper surface and the side surface of the top edge ring 125 including the step part 1251. The thickness of the formed protective film 50 is preferably approximately 0.1-200 μm. When the thickness is thinner than 0.1 μm, the protective effect during the etching treatment is low and the life of the top edge ring 125 cannot be lengthened. When the thickness is thicker than 200 μm, the protective film 50 is more likely to be peeled off due to stress. Therefore, the thickness of the protective film 50 is within the above-described range.

Note, by rounding the two edge parts 1251a and 1251b configuring the step part 1251 of the top edge ring 125 so as to have curvatures, the protective film 50 is more likely to be formed, and by thickening the film thickness of the protective film 50 in the concave part, the life is lengthened.

As described above, when the protective film 50 is formed on the upper surface and the side surface of the top edge ring 125, due to the existence of the protective film 50 having the plasma tolerance, the thickness of the top edge ring 125 after the etching treatment for the predetermined period is almost constant.

The protective film 50 used in the third embodiment is the same as those described in the first embodiment, so a description thereof is omitted.

Also with the third embodiment, the same effect as the first embodiment can be obtained.

While certain embodiments have been described, these embodiments have been presented by way of example only; and are not intended to limit the scope of the inventions. Indeed, the novel embodiments described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirits of the inventions.

What is claimed is:

1. An etching device, comprising:
a treatment target holding device that hold a treatment target in a chamber; and
a plasma generation device that turns gas introduced into the chamber into plasma, wherein
the etching device etches the treatment target using generated plasma,
the treatment target holding device comprises
a treatment target supporting member that serves as an electrode and on which the treatment target is mounted,
a ring-shaped focus ring that is provided in an outer circumference of the treatment target supporting member and that has a step part in an inner circumference having a height lower than those of other portions and having the same height as those of an upper surface of the treatment target supporting member, and
a protective film containing yttria that is provided in a predetermined region of the focus ring,
the treatment target supporting member has a positioning pin that fixes the focus ring on a focus ring mounting region on which the focus ring is mounted,
the focus ring has a cavity part in a position corresponding to the positioning pin, and
the protective film is formed on a bottom surface and a side surface that configure the step part of the focus ring and on an upper surface of the focus ring corresponding to a formation position of the cavity part.

2. The etching device according to claim 1, wherein
a thickness of the protective film is 0.1 μm or more and 200 μm or less.

3. The etching device according to claim 1, wherein
the protective film includes an yttrium oxide particle, has a film thickness of 10 μm or more and 200 μm or less, and has a film density of 90% or more,
an area ratio of the yttrium oxide particle having an observable particle border existed in a unit area of 200 μm×200 μm is 0-80%, and
an area ratio of the yttrium oxide particle having a not-observable particle border is 20-100%.

4. The etching device according to claim 1, wherein
a thickness of the protective film is formed such that a thickness of a region of the focus ring where the protective film is formed is the same as a predetermined thickness when a thickness of a region of the focus ring where the protective film is not formed reaches the predetermined thickness with which the focus ring is to be replaced according to a progress of an etching treatment.

5. A focus ring that is provided in an outer circumference of a treatment target supporting member arranged in a chamber of an etching device, that includes a step part in an inner circumference that is lower than other portions and has the substantially same height as those of an upper surface of the treatment target supporting member, and that has a ring shape, comprising:
a cavity part arranged in a position corresponding to a positioning pin that fixes the focus ring provided on the treatment target supporting member; and
a protective film containing yttria, which is provided on a bottom surface and a side surface that configure the step part and on an upper surface of the focus ring corresponding to a formation position of the cavity part.

6. The focus ring according to claim 5, wherein
a thickness of the protective film is 0.1 μm or more and 200 μm or less.

7. The focus ring according to claim 5, wherein
the protective film includes an yttrium oxide particle, has a film thickness of 10 μm or more and 200 μm or less, has a film density of 90% or more,
an area ratio of the yttrium oxide particle having an observable particle border existed in a unit area of 20 μm×20 μm is 0-80%, and
an area ratio of the yttrium oxide particle having not-observable particle border existed in a unit area of 20 μm×20 μm is 20-100%.
